(19) United States
(12) Patent Application Publication
(10) Pub. No.: US 2026/0221934 A1
(43) Pub. Date: Jul. 30, 2026

(54) A TOTAL INTERNAL PHOTONIC ABSORPTION HEXAGONAL SYSTEM

(71) Applicant: TIPA TECH LIMITED, Watford (GB)

(72) Inventor: Shamir pravinchandra BUDHDEO, Pinner (GB)

(21) Appl. No.: 19/147,326

(22) PCT Filed: Jan. 10, 2024
(86) PCT No.: PCT/IN2024/050026

§ 371 Date: Jul. 11, 2025

(30) Foreign Application Priority Data
Jan. 11, 2023 (IN) 202321002371

(51) Int. Cl. H02S 40/22; H02S 30/10; H02S 40/40; H10F 19/30; H10F 19/90

(52) U.S. Cl. CPC H02S 40/22; H02S 30/10; H02S 40/40; H10F 19/30; H10F 19/904

(57) ABSTRACT

A Total Internal Photonic Absorption Hexagonal System (100) comprising a body (100), a plurality of solar cell strips (104), a dome with staggered steps (106), optionally a biconcave lens (108), a conical mirror (110) and a base cap (112). The body (102) is having a first end, a second end, an internal surface and an external surface, wherein the first end is open to allow light to pass through. The plurality of solar cell strips (104) is provided on the internal surface of the body (102) forming a hexagonal pattern. The dome with staggered steps (106) is provided at the first end of the body (102), wherein the dome with staggered steps (106) refracts incoming light into the opening provided at the first end of the body (102). The biconcave lens (108) is provided at the first end of the body (102) to refract light coming from the dome with staggered steps (106) towards the solar cell strips (104). The conical mirror (110) is provided at the second of the body (102) to reflect the incoming light towards the solar cell strips (104). The base cap (112) is provided at the second end of the body (102) to provide a flat bottom.

### FIELD OF THE INVENTION

The present invention relates to a Total Internal Photonic Absorption Hexagonal System for generating electricity from solar energy. It is particularly applicable to a tube-shaped Total Internal Photonic Absorption Hexagonal System for the generation of solar power wherein the temperature of the Total Internal Photonic Absorption Hexagonal System is maintained to increase the efficiency of the system.

### BACKGROUND OF THE INVENTION

Conventional photo voltaic systems are flat and rectangular in geometry. Such Total Internal Photonic Absorption Hexagonal Systems are limited by the amount of surface area and the total quantum of photons it can absorb. The thin film PV systems, unlike silicon PV systems are more flexible and are cheaper than silicon PV systems. However, thin film PV systems have a lower efficiency than their equivalent silicon counterparts. When surface area is a premium, most people will opt for a greater production using silicon cells as the total cost of a system is measured in £ per watt generated. Hence thin film technology has not displaced their more expensive silicon counterparts.

In current PV panels, be they thin film or silicon solar cells, electricity production is heavily influenced by the orientation of the PV panel to the incidence of light. In the UK, the best production is achieved on the SW orientation with a 30-40 degree elevation to the horizontal. Surface area is a major issue on embedded building generation and as such solar silicon panels are the preferred choice for embedded generation. High planar footprint is the main limitation of the flat rectangular geometry PV system.

To overcome the above limitations, few photovoltaic systems are known in the art. However, such photo voltaic systems have the limitation that during the working, the temperature inside such system rises to undesirably high level. Such high operating temperatures negatively affect the efficiency of the Total Internal Photonic Absorption Hexagonal System. Plastic materials used for fabrication of the Total Internal Photonic Absorption Hexagonal System body, which are bad conductor of heat and prevent transfer of heat from the system to the surroundings. To lower the temperature, such systems require heat exchangers, which further increase the fabrication cost of the cylindrical Total Internal Photonic Absorption Hexagonal Systems.

Further, the solar pipe disclosed in the Great Britain patent applications GB2586003 and GB2567539A requires flexible hexagonal solar panels which break easily and require careful handling.

Thus, there remains a need for alternative designs of Total Internal Photonic Absorption Hexagonal Systems that address the problems mentioned above while remaining economical, efficient, easy to handle and convenient to use.

### OBJECTS

Some of the objects of the present disclosure, which at least one embodiment herein satisfies, are as follows:

An object of the present disclosure is to ameliorate one or more problems of the prior art or to at least provide a useful alternative.

Another object of the present disclosure is to provide a Total Internal Photonic Absorption Hexagonal System for generating electricity from solar energy.

Yet another object of the present disclosure is to provide a Total Internal Photonic Absorption Hexagonal System that does not require heat exchanger and flexible photo voltaic (PV) panels.

Other objects and advantages of the present disclosure will be more apparent from the following description, which is not intended to limit the scope of the present disclosure.

### SUMMARY OF THE DISCLOSURE

The present invention discloses a Total Internal Photonic Absorption Hexagonal System having a body, a plurality of solar cell strips, a dome with staggered steps, optionally a biconcave lens, a conical mirror and a base cap. The body is having a first end, a second end, an internal surface and an external surface, wherein the first end is open to allow light to pass through. The plurality of solar cell strips is provided on the internal surface of the body forming a hexagonal pattern. The dome with staggered steps is provided at the first end of the body, wherein the dome with staggered steps refracts incoming light into the opening provided at the first end of the body. The biconcave lens is provided at the first end of the body to refract light coming from the dome with staggered steps towards the solar cell strips. The conical mirror is provided at the second of the body to reflect the incoming light towards the solar cell strips. The base cap is provided at the second end of the body to provide a flat bottom. The shape of the body is selected from cylindrical, cuboidal, triangular or hexagonal tube. The solar cell strips are perovskite or monocrystalline and multijunction panels. The solar cell strips are provided on the internal surface of the body forming a hexagonal pattern.

The outer surface of the body is provided with a snap lock to fix the body on the base cap. Further, the body is fabricated from a plastic material having fillers of high conductivity material such as aluminum, copper, silver, graphene, graphite. The weight percentage of the filler used in plastic is selected from the range of 1 weight percent to 5 weight percent.

The dome with staggered steps is provided on the body with a dome gasket and the base cap is provided with a base gasket to make the system airtight. The body is provided with a plurality of apertures to provide electrical connections.

The dome with staggered steps, base cap, first end and second end of body are provided with coupling means to detachably attach the dome with staggered steps with the first end of the body and detachably attach the base cap with the second end of the body. The coupling means is selected from threaded coupling, nuts and bolt coupling and adhesive coupling.

### BRIEF DESCRIPTION OF THE DRAWINGS

FIG. 1 is a front view of one Total Internal Photonic Absorption Hexagonal System embodiment constructed in accordance with the present invention.

FIG. 2 is front cross-sectional view of the Total Internal Photonic Absorption Hexagonal System embodiment constructed in accordance with the present invention.

FIG. 3 is a perspective cross-sectional exploded view of the body of Total Internal Photonic Absorption Hexagonal System embodiment constructed in accordance with the present invention.

LIST OF REFERENCE NUMERAL

| | | |
|---|---|---|
| 100 | : | Total Internal Photonic |
| | | Absorption Hexagonal System |
| 102 | : | Body |
| 104 | : | Solar cell strips |
| 106 | : | Dome with staggered steps |
| 108 | : | Biconcave lens |
| 110 | : | Conical mirror |
| 112 | : | Base cap |
| 114 | : | Dome gasket |
| 116 | : | Base gasket |

### DETAILED DESCRIPTION

Embodiments are provided so as to thoroughly and fully convey the scope of the present disclosure to the person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used in the present disclosure is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open-ended transitional phrases and therefore specify the presence of stated features, integers, steps, operations, elements, modules, units and/or components, but do not forbid the presence or addition of one or more other features, integers, steps, operations, elements, components, and/or groups thereof. The particular order of steps disclosed in the method and process of the present disclosure is not to be construed as necessarily requiring their performance as described or illustrated. It is also to be understood that additional or alternative steps may be employed.

The terms first, second, third, etc., should not be construed to limit the scope of the present disclosure as the aforementioned terms may be only used to distinguish one element, component, region, layer or section from another component, region, layer or section. Terms such as first, second, third, etc., when used herein do not imply a specific sequence or order unless clearly suggested by the present disclosure.

Total Internal Photonic Absorption Hexagonal Systems are known in the art. disclose solar pipes, which are cylindrical Total Internal Photonic Absorption Hexagonal Systems having small planar footprints. However, such solar pipes have the limitation that during the working, the temperature inside such a system rises to an undesirably high level. Such high operating temperatures negatively affect the efficiency of the Total Internal Photonic Absorption Hexagonal System. Plastic materials used for fabrication of the Total Internal Photonic Absorption Hexagonal System body, which are bad conductor of heat and prevent transfer of heat from the system to the surroundings. To lower the temperature, such systems require heat exchangers, which further increase the fabrication cost of the cylindrical Total Internal Photonic Absorption Hexagonal Systems.

Further, the solar pipe requires flexible hexagonal solar panels which break easily and require careful handling. Thus, there remains a need for alternative designs of Total Internal Photonic Absorption Hexagonal Systems that address the problems mentioned above while remaining economical, efficient, easy to handle and convenient to use.

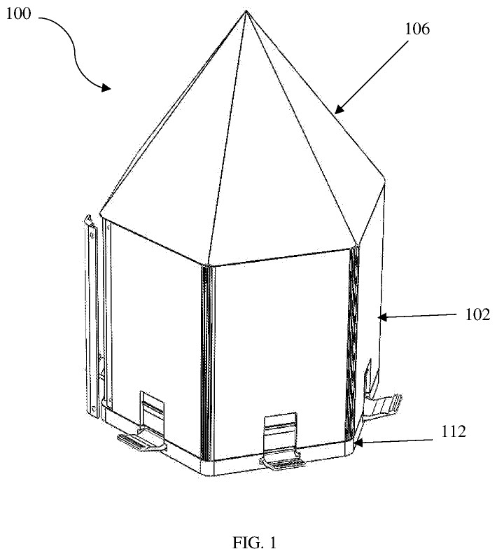

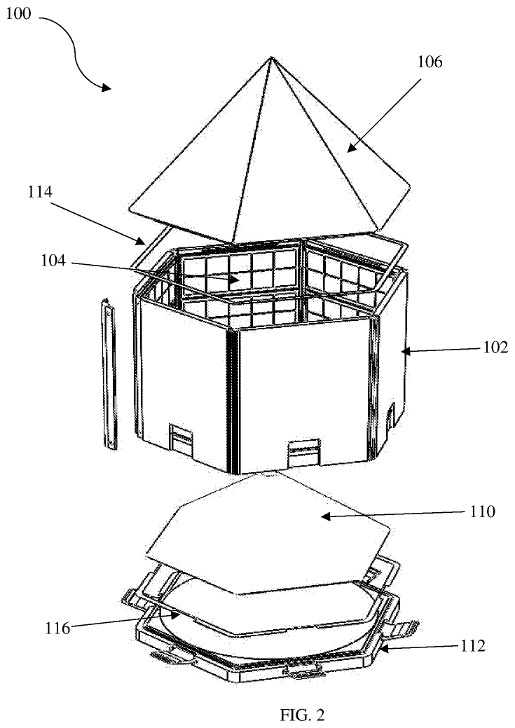

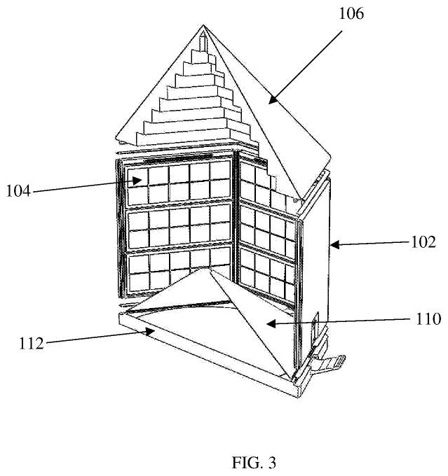

In an aspect, the present disclosure provides a Total Internal Photonic Absorption Hexagonal System which solves the problem mentioned hereinabove. FIG. 1, FIG. 2, and FIG. 3 illustrate different perspective views of the Total Internal Photonic Absorption Hexagonal System (100) according to one embodiment of the present invention. The Total Internal Photonic Absorption Hexagonal System (100) is having a body (100), a plurality of solar cell strips (104), a dome with staggered steps (106), optionally a biconcave lens (108), a conical mirror (110) and a base cap (112). The body (102) is having a first end, a second end, an internal surface and an external surface, wherein the first end is open to allow light to pass through. The plurality of solar cell strips (104) is provided on the internal surface of the body (102) forming a hexagonal pattern. The dome with staggered steps (106) is provided at the first end of the body (102), wherein the dome with staggered steps (106) refracts incoming light into the opening provided at the first end of the body (102). The biconcave lens (108) is provided at the first end of the body (102) to refract light coming from the dome with staggered steps (106) towards the solar cell strips (104). The conical mirror (110) is provided at the second of the body (102) to reflect the incoming light towards the solar cell strips (104). The base cap (112) is provided at the second end of the body (102) to provide a flat bottom.

The shape of the body (102) is selected from cylindrical, cuboidal, triangular or hexagonal tube. In a preferred embodiment, the shape of the body (100) is cylindrical.

In an embodiment, the solar cell strips (104) are perovskite or monocrystalline and multijunction panels. This overcomes the drawback of the flexible panels used in the prior art, which are prone to breaking and difficult to handle. The solar cell strips (104) are provided on the internal surface of the body (102) forming a hexagonal pattern, wherein no bending of solar cell strips (104) is required.

In another embodiment, the outer surface of the body (104) is provided with snap lock to fix the body on the base cap, wherein the gridlines provide the required strength and wall with less thickness is used. This reduces the heat resistance offered by the wall of the body (102) helps in heat transfer from inside of the body to the outside atmosphere.

Further, the body (102) is fabricated from a plastic material having fillers of high conductivity material such as aluminum, copper, silver, graphene, graphite. The weight percentage of the filler used in plastic is selected from the range of 1 weight percent to 5 weight percent. In an exemplary embodiment, graphene is used as a filler and the weight percentage of the graphene in plastic is 2 weight percentage.

The body (100) is made of a polymer composite material which contains graphene fillers of 2% by weight. The polymer material by itself has low thermal conductivity but by the addition of graphene filler (which has a thermal conductivity of 4000 W/m/K which is 10 times higher than of copper) in the composite the thermal conductivity is significantly increased. This will aid in maintaining the temperature of the solar cells at optimum operating temperature of 25° C. The excess heat absorbed is transferred to the atmosphere around it as the thermal resistance of the wall has been significantly reduced. Moreover, the heating caused at the outside surface of the body will cause the formation of micro air currents as the heated air rises and cooler air rushes to take its place.

The dome with staggered steps (106) is provided on the body (102) with a dome gasket (114) and the base cap (112) is provided with a base gasket (116) to make the system (100) airtight. A vacuum is created inside the system (100) to prevent condensation of vapors or rise in temperature of system (100) due to heating of gases by radiation. The body (102) is provided with a plurality of apertures to provide electrical connections.

In an embodiment, the dome with staggered steps (106), base cap (112), first end and second end of body (102) are provided with coupling means to detachably attach the dome with staggered steps (106) with the first end of the body (102) and detachably attach the base cap (112) with the second end of the body (102). The coupling means is selected from threaded coupling, nuts and bolt coupling and adhesive coupling. In an exemplary embodiment, the coupling means is threaded coupling.

In an exemplary embodiment, the base cap (112) is designed to facilitate the inclusion of a conical mirror, a non-return valve and electrical outlet connector. The cap (112) is sealed by means of gaskets and O-rings. The internal volume of the system (100) is at a vacuum of around 0.4 bar. As air can absorb some of the solar electromagnetic radiation, this would cause the heating of the air inside the system (100) if it existed. The thermal conduction of heat drop at the interface layer of different phases and so the system (100) being evacuated would be much more efficient in terms of keeping the silicon solar cells at ideal operating conditions.

The top dome, optionally a biconcave lens and the conical mirror are designed and constructed so that any form of incident light, it be direct or ambient, will be focused towards the interior of the dome. By means of Snell's laws of photo refraction the ideal shape of the dome was calculated and designed. By running optical simulations of the designs it was concluded that the dome design converges light coming from 360° azimuth and 180° elevation of the sun with minimal light escaping the present system (100) and further increase the efficiency with the conical mirror.

In a preferred embodiment, the height of the conical mirror (110) is half of the height of the body (102). This is the optimized height of the conical mirror (110), wherein there will be no shadowing effect due to the conical mirror (100) and maximum amount of light will reach to the solar cells (104) provided at the bottom part of the body (102).

### TECHNICAL ADVANCEMENTS

The present disclosure described hereinabove has several technical advantages including, but not limited to, a Total Internal Photonic Absorption Hexagonal System.

The technical advancements are enumerated hereunder:
The Hexagonal body of the solar system maximize the utilization of space when multiple Total Internal Photonic Absorption Hexagonal Systems are used as compared to cylindrical solar systems.
The Hexagonal body opens up to form flat panels that are easy to manufacture, assemble, dismantle and transport from one place to another.
With the use of dome with staggered steps, there is no requirement of bi-concave lens.
The conical mirror at the base of the system reflects all the incoming light towards the wall of the system for total photonic absorption of the incoming light by the solar cells. A conical mirror provides more efficacy as compared to a convex mirror. Convex mirror reflects a part of light out of the Total Internal Photonic Absorption Hexagonal System. However, a conical mirror reflects all the light to the walls.
The Total Internal Photonic Absorption Hexagonal System has drastically reduced the horizontal planar footprint which conventional flat plate solar panels would occupy. This has advantages like better cooling, space saving, and a higher number of modules can be placed using the same surface area as compared to the flat plate panel.
Economical as no heat exchanger is required to cool the Total Internal Photonic Absorption Hexagonal System.
Easy to fabricate as flexible PV panels are not required and no heat exchanger is required.
Lower weight due to the use of gridline body and no requirement of heat exchanger.
No environmental damage to the PV panels as vacuum is maintained inside the Total Internal Photonic Absorption Hexagonal System.
Greater operating range due to the dome with staggered steps, bi-concave lens, conical mirror. Thus, greater generation of energy per sqm. The dome design converges light coming from 0°-360° azimuth and 0°-180° elevation of the sun with minimal light escaping the present system and further increases the efficiency with the convex mirror.
Standard PV panels have thick glass to help the PV panels avoid environmental damage but also to help the rain self-clean. The weight of the glass adds to the installation cost and overall cost of the PV plus the glass heats up and reduces overall PV effectiveness. A vacuum is maintained in the Total Internal Photonic Absorption Hexagonal System of the present invention to prevent the environmental damage. No glass is required to cover the PV panels. Therefore, the system of the present invention is lightweight and economical to manufacture.
The present photovoltaic system uses standard M12-M20 monocrystalline PV cells. These are the highest wattage and area PV cells in the market but most importantly they are standardized. This means there is NO cutting or extra step. Existing PV cells are used to produce a greater amount of energy for longer and more energy is produced per sqm compared to a normal PV panel.
The pipe is now actually hexagonal. A hexagonal structure, like a beehive allows for less wasted space and a greater overall production of energy per sqm.
The hexagonal structure is obtained from a flat one-piece design and as such the current robotic processes for creating panels only need to be tweaked. This will help penetration of the patent and increase the risk of infringement which ultimately increases the value of a patent. Flat panels are easier to ship, and the lack of glass reduces the cost or transportation.
The cells in the present photovoltaic system do not need laminating. Laminating is the single largest bottleneck in PV production. Lamination increases the longevity of panels protecting the silicon from long term oxidization issues. The glass panel on top of a PV panels provides it with physical protection from the weather elements.
The present photovoltaic system once sealed with the hexagonal shape, the lens and the mirror/base, is hermetically closed and nitrogen at 2 bar is added. Nitrogen is non oxidizing and the positive pressure reduces the ingress of Oxygen. This is critical as it can immediately allow the use of perovskite PV cells which degrade in oxygen and during the lamination process.
In normal PV systems, the number of busbars or wires embedded within the solar cell is limited as it causes shading. In a normal PV panel the photon has only one chance of being absorbed and so there is a tradeoff between busbars which increase conduction efficiency and the shading they cause. With the present photovoltaic system, we can increase the busbars beyond the current 7 in the M12 cells to over 14 as the shading has limited impact as the photon is reflected.
Overall the present photovoltaic system is lighter, lower in cost to install and produces more energy per sqm at a lower cost than normal PV cells. The cost reduction is at least 50% lower than current PV panels. Current costs are £0.10 per KWH from a solar PV array. The manufacturing costs will be less than £0.05 per KWH.

The numerical values given for various physical parameters, dimensions, and quantities are only approximate values and it is envisaged that the values higher than the numerical value assigned to the physical parameters, dimensions, and quantities fall within the scope of the invention unless there is a statement in the specification to the contrary.

While considerable emphasis has been placed herein on the specific features of the preferred embodiment, it will be appreciated that many additional features can be added and that many changes can be made in the preferred embodiment without departing from the principles of the disclosure. These and other changes in the preferred embodiment of the disclosure will be apparent to those skilled in the art from the disclosure herein, whereby it is to be distinctly understood that the foregoing descriptive matter is to be interpreted merely as illustrative of the disclosure and not as a limitation.

We claims:

1. A Total Internal Photonic Absorption Hexagonal System (100) for converting solar energy into electricity, wherein the system (100) comprises:
a) a body (102) is having a first end, a second end, an internal surface and an external surface, wherein the first end is open to allow light to pass through;
b) a plurality of solar cell strips (104) is provided on the internal surface of the body (102) forming a hexagonal pattern;
c) a dome with staggered steps (106) is provided at the first end of the body (102), wherein the dome with staggered steps (106) refracts incoming light into the opening provided at the first end of the body (102);
d) optionally a biconcave lens (108) is provided at the first end of the body (102) to refract light coming from the dome with staggered steps (106) towards the solar cell strips (104);
e) a conical mirror (110) is provided at the second of the body (102) to reflect the incoming light towards the solar cell strips (104); and
f) a base cap (112) is provided at the second end of the body (102) to provide a flat bottom.

2. The Total Internal Photonic Absorption Hexagonal System (100) as claimed in claim 1, wherein shape of the body (102) is a hexagonal tube and the body (102) unfolds to form a flat panel.

3. The Total Internal Photonic Absorption Hexagonal System (100) as claimed in claim 1, wherein the solar cell strips (104) is selected from a group of perovskite or monocrystalline and multijunction panels.

4. The Total Internal Photonic Absorption Hexagonal System (100) as claimed in claim 1, wherein the outer surface of the body (104) is provided with snap lock to fix the body on the base cap.

5. The Total Internal Photonic Absorption Hexagonal System (100) as claimed in claim 1, wherein the body (102) is fabricated from a plastic material optionally having fillers of high conductivity material such as aluminum, copper, silver, graphene, graphite.

6. The Total Internal Photonic Absorption Hexagonal System (100) as claimed in claim 5, wherein weight percentage of fillers used in plastic is selected from the range of 1 weight percent to 5 weight percent.

7. The Total Internal Photonic Absorption Hexagonal System (100) as claimed in claim 1, wherein the dome with staggered steps (106) is provided on the body (102) with a dome gasket (114) and the base cap (112) is provided with a base gasket (116) to make the system (100) airtight.

8. The Total Internal Photonic Absorption Hexagonal System (100) as claimed in claim 1, wherein the body (102) is provided with a plurality of apertures to provide electrical connections.

9. The Total Internal Photonic Absorption Hexagonal System (100) as claimed in claim 1, wherein the dome with staggered steps (106), base cap (112), first end and second end of body (102) are provided with coupling means to detachably attach the dome with staggered steps (106) with the first end of the body (102) and detachably attach the base cap (112) with the second end of the body (102).

10. The Total Internal Photonic Absorption Hexagonal System (100) as claimed in claim 9, wherein the coupling means is selected from snap lock, threaded coupling, nuts and bolt coupling and adhesive coupling.
